(19) United States
(12) Patent Application Publication
(10) Pub. No.: US 2011/0044107 A1
(43) Pub. Date: Feb. 24, 2011

(54) Nonvolatile semiconductor memory device

(75) Inventor: Osamu Wada, Kanagawa (JP)

Correspondence Address: POSZ LAW GROUP, PLC, 12040 SOUTH LAKES DRIVE, SUITE 101, RESTON, VA, 20191, US

(73) Assignee: KABUSHIKI KAISHA TOSHIBA, Tokyo (JP)

(21) Appl. No.: 12/659,131

(22) Filed: Feb. 26, 2010

(30) Foreign Application Priority Data
Aug. 21, 2009 (JP) 2009-192275

(51) Int. Cl. G11C 16/04; G11C 16/06

(52) U.S. Cl. 365/185.05; 365/185.23

(57) ABSTRACT

A nonvolatile semiconductor memory device has a drawing wiring drawn out from one end of a gate electrode and connected to a terminal, and has another drawing wiring drawn out from the other end of the gate electrode and connected to a terminal. Lengths of the two drawing wirings are set different from each other.

### CROSS-REFERENCE TO RELATED APPLICATIONS

This application is based upon and claims the benefit of priority from the prior Japanese Patent Application No. 2009-192275, filed on Aug. 21, 2009; the entire contents of which are incorporated herein by reference.

### BACKGROUND OF THE INVENTION

1. Field of the Invention

The present invention relates to a nonvolatile semiconductor memory device, and, more particularly to a nonvolatile semiconductor memory device preferably applied to a dielectric-film-breakdown semiconductor memory element in which data can be written only once by breaking down a gate dielectric film of a metal-oxide semiconductor (MOS) transistor.

2. Description of the Related Art

In recent semiconductor integrated circuits, a one-time programmable (OTP) memory in which data can be written only once has been an essential element to store redundancy replacement information of a memory having redundancy, such as a dynamic random access memory (DRAM) and a static random access memory (SRAM), as well as identification (ID) information specific to a chip and tuning information of an analog circuit.

Mainly, an electrically writable fuse element is used as a memory element used for the OTP memory, and fuse elements such as a gate-dielectric-film breakdown fuse element and a current-fuse element have been developed.

The current-fuse element is a system of changing a resistance, by passing a large current to a wiring, fusing a wiring, and changing a wiring structure. On the other hand, the gate-dielectric-film breakdown fuse element is an antifuse system of reducing a resistance by causing a gate dielectric film of a MOS transistor to generate dielectric breakdown by applying a high voltage to the gate dielectric film (“Pure CMOS One-time Programmable Memory using Gate-Ox Anti-fuse”, Proceedings of the IEEE 2004 Custom Integrated Circuits Conference, PP. 469-472).

The gate-dielectric-film breakdown antifuse element stores data based on a change in conductivity due to breakdown of a gate dielectric film of a transistor. Therefore, when the gate-dielectric-film breakdown antifuse element is mounted on a semiconductor memory device, an additional manufacturing process is not required. Therefore, the semiconductor memory device can be manufactured at low cost. Furthermore, when the gate-dielectric-film breakdown antifuse element is mounted in a mixed manner on a semiconductor chip mounted with a semiconductor memory device, a semiconductor logic circuit, or an analog circuit, the performance of these circuits is not degraded.

While the gate-dielectric-film breakdown antifuse element has such advantages, its reading-current characteristic distribution tends to vary after writing (“A 65 nm Pure CMOS One-time Programmable Memory Using a Two-Port Antifuse Cell Implemented in a Matrix Structure”, IEEE A-SSCC, PP. 212-215, 2007).

For example, Japanese Patent Application Laid-open No. 2009-54662 discloses the following method. To suppress variation of a resistance after an antifuse element is dielectrically broken down, an element isolation region is provided in a region at an opposite side of a diffusion layer region from the viewpoint of a channel region, without passing through other electrodes to which the same potential as that of the diffusion layer region is applied. With this arrangement, an electric field of a gate dielectric film is set nonuniform, and its field intensity is set higher toward the diffusion layer region, thereby increasing the probability of the occurrence of dielectric breakdown at a portion nearer the diffusion layer region.

However, according to the method disclosed in Japanese Patent Application Laid-open No. 2009-54662, a current flows in dispersion to a gate electrode, depending on a position of the occurrence of a breakdown spot. Therefore, electromigration of silicide is not sufficiently performed occasionally, and there is problem that the reading-current characteristic distribution after writing tends to vary.

### BRIEF SUMMARY OF THE INVENTION

A nonvolatile semiconductor memory device according to an embodiment of the present invention comprises: a field-effect transistor having a gate electrode formed on a semiconductor substrate via a gate dielectric film; a first drawing wiring drawn out from one end of the gate electrode; a second drawing wiring drawn out from the other end of the gate electrode and having a length different from that of the first drawing wiring; a first terminal that applies a voltage to the gate electrode via the first drawing wiring; a second terminal that applies a voltage to the gate electrode via the second drawing wiring; and a wiring that is connected to the first terminal and the second terminal, supplies a voltage used to break down the gate dielectric film, and is used to read a change in a resistance following breakdown of the gate dielectric film.

A nonvolatile semiconductor memory device according to an embodiment of the present invention comprises: a first drawing wiring drawn out from one end of the gate electrode; a second drawing wiring drawn out from the other end of the gate electrode; a first terminal that applies a voltage to the gate electrode via the first drawing wiring; a second terminal that applies a voltage to the gate electrode via the second drawing wiring; a first wiring that is connected to the first terminal and supplies a voltage used to break down the gate dielectric film; and a second wiring that is connected to the second terminal and is used to read a change in a resistance following breakdown of the gate dielectric film.

A nonvolatile semiconductor memory device according to an embodiment of the present invention comprises: a gate electrode arranged via a gate dielectric film to cross an impurity diffusion layer on a semiconductor substrate; a first wiring that supplies a voltage used to break down the gate dielectric film via one end of the gate electrode; and a second wiring that reads a change in a resistance following breakdown of the gate dielectric film via the other end of the gate electrode.

### BRIEF DESCRIPTION OF THE DRAWINGS

FIG. 1 is a block diagram of a schematic configuration of a nonvolatile semiconductor memory device according to a first embodiment of the present invention;

FIG. 2 is a plan view of a schematic configuration of the antifuse element in FIG. 1;

FIG. 3 is a cross-sectional view of a schematic configuration of the antifuse element in FIG. 1;

FIG. 4 is a plan view of an example of a position of occurrence of a breakdown spot of the antifuse element in FIG. 1;

FIG. 5 is a circuit diagram of a schematic configuration of a memory cell using an antifuse element applied to a nonvolatile semiconductor memory device according to a second embodiment of the present invention;

FIG. 6 is a plan view of a schematic configuration of the antifuse element in FIG. 5; and

FIG. 7 is a plan view of an example of a position of occurrence of a breakdown spot of the antifuse element in FIG. 6.

### DETAILED DESCRIPTION OF THE INVENTION

Exemplary embodiments of a nonvolatile semiconductor memory device according to the present invention will be explained below in detail with reference to the accompanying drawings. The present invention is not limited to the embodiments.

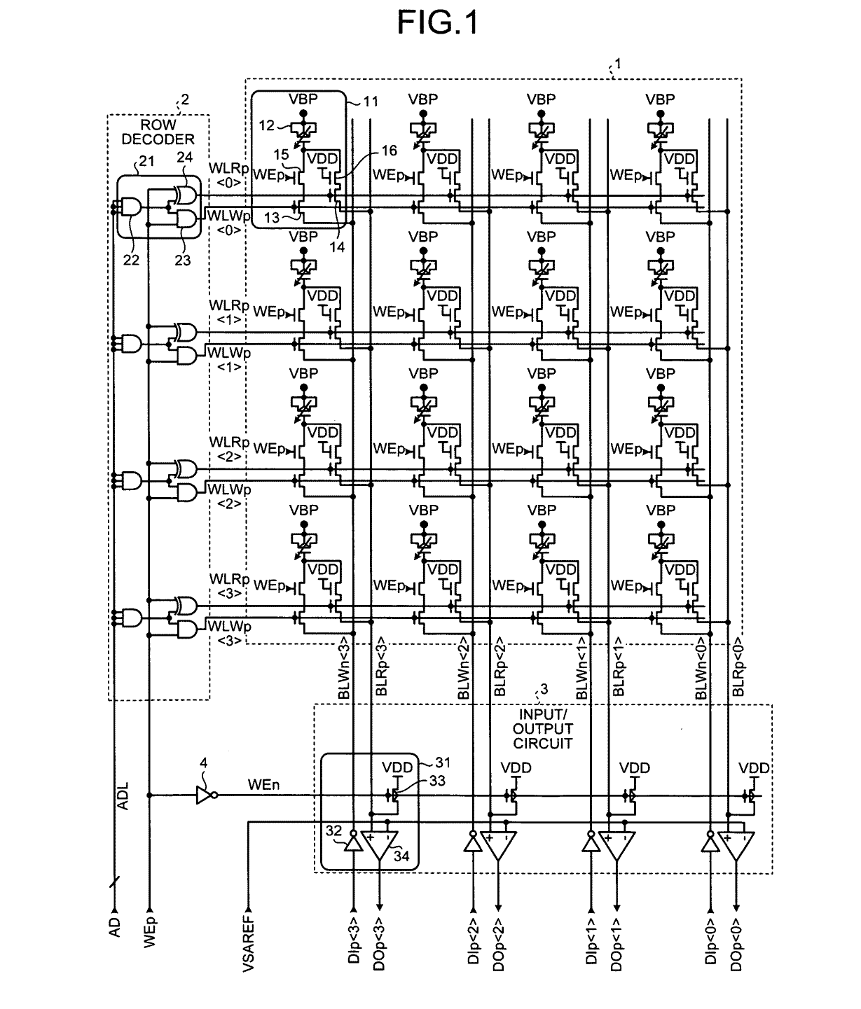

FIG. 1 is a block diagram of a schematic configuration of a nonvolatile semiconductor memory device according to a first embodiment of the present invention.

In FIG. 1, a memory cell array 1, a row decoder 2, and an input/output circuit 3 are mainly provided in the nonvolatile semiconductor memory device. A plurality of memory cells 11 are provided in the memory cell array 1, and are arranged in a matrix shape. In an example in FIG. 1, while the memory cells 11 are arranged for 4×4=16 bits, the arrangement is not limited thereto in the present invention.

A pair of word lines including a write word line WLWp<0> and a read word line WLRp<0>, a pair of word lines including a write word line WLWp<1> and a read word line WLRp<1>, a pair of word lines including a write word line WLWp<2> and a read word line WLRp<2>, and a pair of word lines including a write word line WLWp<3> and a read word line WLRp<3> are connected to each row of the memory cells 11, respectively. Similarly, a pair of bit lines including a write bit line BLWn<0> and a read bit line BLRp<0>, a pair of bit lines including a write bit line BLWn<1> and a read bit line BLRp<1>, a pair of bit lines including a write bit line BLWn<2> and a read bit line BLRp<2>, and a pair of bit lines including a write bit line BLWn<3> and a read bit line BLRp<3> are connected to each column of the memory cells 11, respectively. Indexes “p” and “n” assigned to signal line names in the above represent whether logic of each signal line is “positive logic” or “negative logic”.

An antifuse element 12, a write transistor 13, a read transistor 14, a write control transistor 15, and a read barrier transistor 16 are provided in each of the memory cells 11. A field-effect transistor is provided in the antifuse element 12. Data is stored based on a change in conductivity due to breakdown of a gate dielectric film of the field-effect transistor. A structure having a silicide layer laminated on a polycrystalline silicon layer can be used for a gate electrode of the field-effect transistor.

The write word lines WLWp<0> to WLWp<3> are connected to gates of the write transistors 13, for each of the memory cells 11 constituting a row. A write control signal WEp is input to a gate of the write control transistor 15. The write bit lines BLWn<0> to BLWn<3> are connected to sources of the write transistors 13, for each of the memory cells 11 constituting a column. The read word lines WLRp<0> to WLRp<3> are connected to gates of the read transistors 14, for each of the memory cells 11 constituting a row. A power source potential VDD is connected to a gate terminal of the read barrier transistor 16. The read bit lines BLRp<0> to BLRp<3> are connected to a source terminal of the read transistor 14, for each of the memory cells 11 constituting a column.

In the row decoder 2, a word-line drive circuit 21 is provided in each of the memory cells 11 constituting a row. Each word-line drive circuit 21 is connected to a row-address signal line ADL. Each word-line drive circuit 21 receives a row address signal AD via the row-address signal line ADL, and can selectively drive an optional one of the write word lines WLWp<0> to WLWp<3> and the read word lines WLRp<0> to WLRp<3>.

A row-selection logic circuit 22, a write-word-line drive circuit 23, and a read-word-line drive circuit 24 are provided in the word-line drive circuit 21. An AND circuit is provided in the row-selection logic circuit 22 and the write-word-line drive circuit 23. An exclusive-OR (XOR) circuit is provided in the read-word-line drive circuit 24. The row address signal AD is input to the row-selection logic circuit 22. An output of the row-selection logic circuit 22 and a write-operation control signal WEp are input to the write-word-line drive circuit 23 and the read-word-line drive circuit 24.

A data input/output buffer 31 is provided in each of the memory cells 11 constituting a column, in the input/output circuit 3. The data input/output buffer 31 receives write signals DIp<0> to DIp<3> given from the outside, and can drive the write bit lines BLWn<0> to BLWn<3>. The data input/output buffer 31 amplifies a read signal read via the read bit lines BLRp<0> to BLRp<3>, and can output amplified read signals DOp<0> to DOp<3>.

A write-bit-line drive circuit 32, a write-disturbance protection circuit 33, and a read sense amplifier 34 are provided in the data input/output buffer 31. An inverter is provided in the write-bit-line drive circuit 32. The write-bit-line drive circuit 32 can drive the write bit lines BLWn<0> to BLWn<3> based on the write signals DIp<0> to DIp<3>. A field-effect transistor is provided in the write-disturbance protection circuit 33. A source of the field-effect transistor is connected to the power source potential VDD, and a drain of the field-effect transistor is connected to the read bit lines BLRp<0> to BLRp<3>. A write control signal WEn of negative logic is input to a gate of the field-effect transistor. The write control signal WEn can be generated by inverting the write control signal WEp by the inverter 4.

A differential amplifier is provided in the read sense amplifier 34. The read bit lines BLRp<0> to BLRp<3> are connected to a plus terminal of the read sense amplifier 34, and a reference potential VSAREF is applied to a minus terminal of the read sense amplifier 34. The read sense amplifier 34 can be configured by elements such as an initialization transistor and a latch circuit in addition to the differential amplifier.

A write operation and a read operation can be performed to the antifuse element 12 by the following procedure.

In the write operation, the write control signal WEp is shifted from a low level potential to a high level potential, and is input to the row decoder 2, the inverter 4, and the gate of the write control transistor 15. A potential of the memory-cell power source VBP is set at a high voltage of about 6 volts. Among the write signals DIp<0> to DIp<3>, a signal of a column including a selected cell is shifted from a low level potential to a high level potential. The write signal is inverted by the write-bit-line drive circuit 32. As a result, among the write bit lines BLWn<0> to BLWn<3> in a selected column, a bit line including a selected cell is set at a low level potential.

A low level potential can be set at a ground potential (0 volt), and a high level potential can be set at the power source potential VDD (3 volts, for example). When the write control signal WEp becomes at a high level potential, the write control transistor 15 is turned on. When the write control signal WEp is input to the inverter 4, the write control signal WEp is inverted. As a result, the write control signal WEn becomes at a low level potential. When the write control signal WEn becomes at a low level potential, a field-effect transistor of the write-disturbance protection circuit 33 is turned on, and all potentials of the read bit lines BLRp<0> to BLRp<3> are set at the power source potential VDD. As a result, erroneous writing to an unselected cell can be prevented.

When the row address signal AD is input to the row decoder 2, the row-selection logic circuit 22 selects a row. An output of the row-selection logic circuit 22 corresponding to a row including a selected cell becomes at a high level potential. When the output of the row-selection logic circuit 22 becomes at a high level potential in a state that the write control signal WEp is at a high level potential, an output of the write-word-line drive circuit 23 corresponding to the selected row becomes at a high level potential. Among the write word lines WLWp<0> to WLWp<3> of the selected row, a potential of a word line including the selected cell becomes at a high level potential.

When a potential of the write word line of the selected row becomes at a high level potential, the write transistor 13 arranged in a row including the selected cell is turned on. The other end of the antifuse element 12 is connected to a write bit line of a selected column via the write control transistor 15 and the write transistor 13. As a result, a high voltage of about 6 volts is applied to both end electrodes of a gate dielectric film of the antifuse element 12. When a state that a high voltage is applied to both end electrodes of the gate dielectric film of the antifuse element 12 is maintained, the gate dielectric film is locally broken down, and a fine breakdown spot constituting a weak current path is formed there. When a relatively large current of about 2 milliamperes is passed by keep applying a high voltage to both end electrodes of the gate dielectric film of the antifuse element 12, migration of silicide occurs, and a relatively low-resistance conductive path is formed. As a result, the gate dielectric film of the antifuse element 12 of the selected cell is broken down, and a resistance of the antifuse element 12 becomes low. Consequently, one-bit information of the selected cell is written.

On the other hand, in the read operation, the write control signal WEp is shifted from a high level potential to a low level potential, and is input to the row decoder 2, the inverter 4, and the gate of the write control transistor 15. A potential of the memory-cell power source VBP is set at a low voltage (about 1 volt, for example), which does not break down the antifuse element 12.

Thereafter, when the write control signal WEp becomes at a low level potential, the write control transistor 15 is turned off. When the write control signal WEp is input to the inverter 4, the write control signal WEp is inverted. As a result, the write control signal WEn becomes at a high level potential. When the write control signal WEn becomes at a high level potential, a field-effect transistor of the write-disturbance protection circuit 33 is turned off, and all potentials of the read bit lines BLRp<0> to BLRp<3> are blocked from the power source potential VDD.

When the row address signal AD is input to the row decoder 2, the row-selection logic circuit 22 selects a row. An output of the row-selection logic circuit 22 corresponding to a row including a selected cell becomes at a high level potential. When the output of the row-selection logic circuit 22 becomes at a high level potential in a state that the write control signal WEp is at a low level potential, an output of the read-word-line drive circuit 24 corresponding to the selected row becomes at a high level potential. Among the read word lines WLRp<0> to WLRp<3> of the selected row, a potential of a read line including the selected cell becomes at a high level potential.

When a potential of the read word line of the selected row becomes at a high level potential, the read transistor 14 arranged in a row including the selected cell is turned on. The other end of the antifuse element 12 is connected to the read bit lines BLRp<0> to BLRp<3> of a selected column via the read barrier transistor 16 and the read transistor 14. As a result, a voltage read from the selected cell is applied to the read sense amplifier 34.

The read sense amplifier 34 compares a voltage read from the selected cell with the reference potential VSAREF, and determines whether data stored in the selected cell is “0” or “1”, based on the difference of a size of a read current obtained at this time.

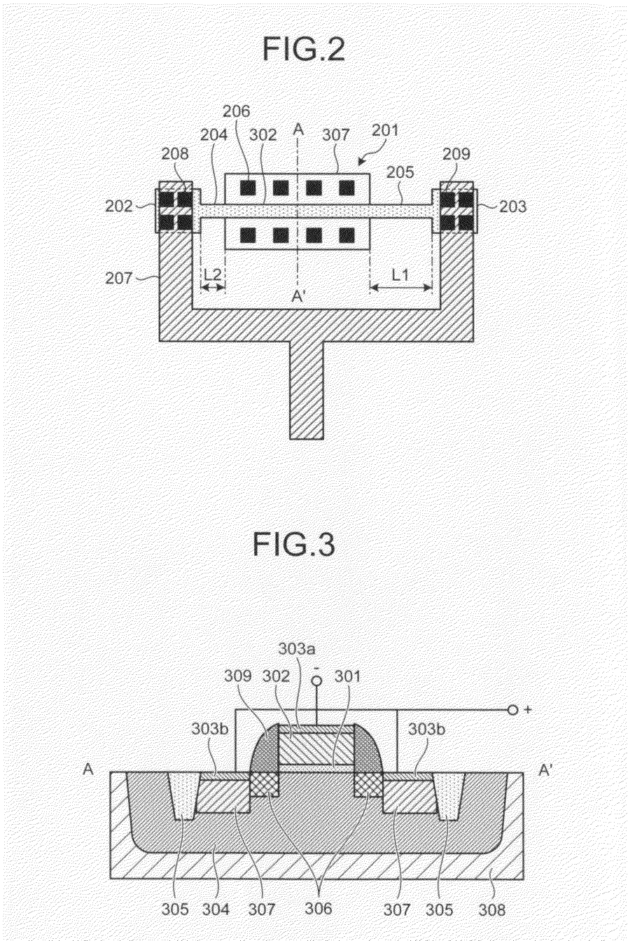

FIG. 2 is a plan view of a schematic configuration of the antifuse element in FIG. 1. FIG. 3 is a cross-sectional view of a schematic configuration of the antifuse element in FIG. 1.

In FIG. 2, a field-effect transistor 201 is provided in the antifuse element 12 in FIG. 1. As shown in FIG. 3, the field-effect transistor 201 has a gate electrode 302 formed on a semiconductor substrate 308 via a gate dielectric film 301. For a material of the semiconductor substrate 308, there can be used Si, Ge, SiGe, SiC, SiSn, PbS, GaAs, InP, GaP, GaN, ZnSe, and GaInAsP, for example. A silicon oxide film, for example, can be used for a material of the gate dielectric film 301. Polycrystalline silicon, for example, can be used for a material of the gate electrode 302.

An N well 304 is formed on the semiconductor substrate 308. An element isolation region 305 is formed in the N well 304. An impurity diffusion layer 307 is formed at both sides of the gate electrode 302, in element regions isolated by the element isolation region 305. The impurity diffusion layer 307 can constitute a source/drain layer of the field-effect transistor 201. A contact 206 that applies a voltage of the memory-cell power source VBP in FIG. 1 to the impurity diffusion layer 307 is formed, on the impurity diffusion layer 307. A sidewall 309 is formed on the gate electrode 302, and a lightly-doped drain (LDD) layer 306 is formed in the semiconductor substrate 308 below the sidewall 309. A silicon oxide film or a silicon nitride film, for example, can be used for a material of the sidewall 309. A silicide layer 303a is formed on the gate electrode 302, and a silicide layer 303b is formed on the impurity diffusion layer 307. The silicide layers 303a and 303b can be configured by metal silicide such as titanium (Ti), cobalt (Co), and nickel (Ni).

A drawing wiring 204 is drawn out from one end of the gate electrode 302, and is connected to a terminal 202. A drawing wiring 205 is drawn out from the other end of the gate electrode 302, and is connected to a terminal 203. The drawing wirings 204 and 205 and the terminals 202 and 203 can use the same structure as that of the gate electrode 302, and can use a structure having a silicide layer laminated on a polycrystalline silicon layer, for example.

The terminals 202 and 203 are connected to a wiring 207 via contacts 208 and 209, respectively. The wiring 207 can be configured by a metal such as Al and Cu. The wiring 207 is connected to the drain of the write transistor 13 via the write control transistor 15 in FIG. 1, and is also connected to the drain of the read transistor 14 via the read barrier transistor 16.

A length L2 of the drawing wiring 204 is set different from a length L1 of the drawing wiring 205. The length L1 of the drawing wiring 205 can be larger than a length L2 of the drawing wiring 204. In this case, preferably, the length L1 of the drawing wiring 205 is set equal to or larger than a gate width of the gate electrode 302.

When data is written into the antifuse element 12 in FIG. 1, a high voltage is applied to the impurity diffusion layer 307 from the memory-cell power source VBP via the silicide layer 303b, and a low voltage is applied to the gate electrode 302 from the write bit lines BLWn<0> to BLWn<3> via the silicide layer 303a. When data is written into the antifuse element 12, a high voltage is also applied to the N well 304. At this time, the difference between potentials applied to the impurity diffusion layer 307 and the gate electrode 302 can be a voltage sufficient enough to break down the gate dielectric film 301, for example, about 6 volts.

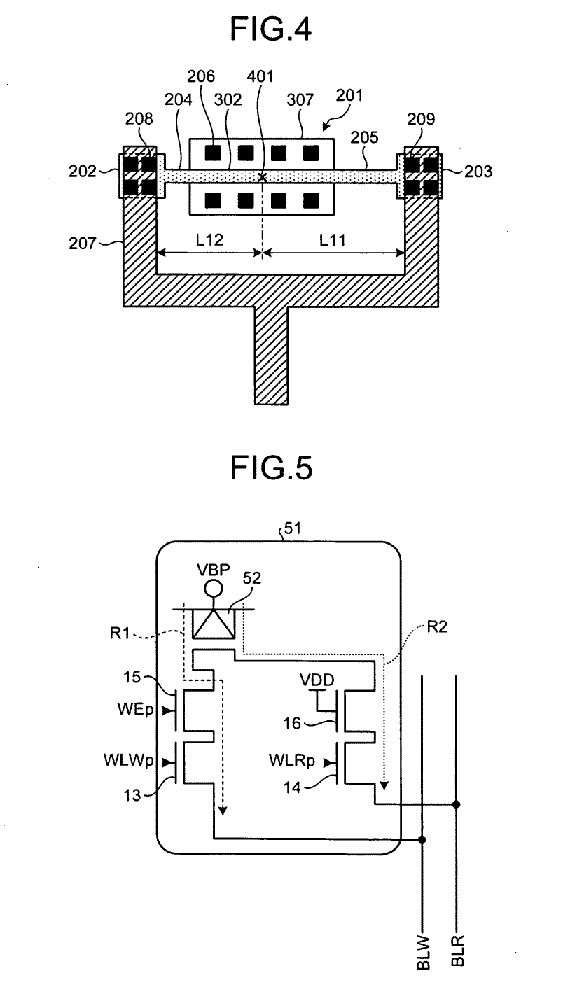

When voltages sufficient enough to break down the gate dielectric film 301 are applied to the impurity diffusion layer 307 and the gate electrode 302, a part of the gate dielectric film 301 is broken down after a channel region is formed below the gate dielectric film 301. As a result, a breakdown spot 401 is formed in the gate dielectric film 301, as shown in FIG. 4.

When the breakdown spot 401 is formed in the gate dielectric film 301, a current flows to the gate electrode 302 via the breakdown spot 401, and a part of the silicide layer 303a is solved by heat generated by the current. Due to this solution, a metal element constituting the silicide layer 303a reaches the silicide layer 303b via the gate electrode 302 and the breakdown spot 401 based on an electromigration phenomenon. As a result, a relatively low-resistance conductive path is formed between the silicide layers 303a and 303b.

When the length L1 of the drawing wiring 205 is set larger than the length L2 of the drawing wiring 204, a current can be passed in concentration to a direction of the drawing wiring 204, even when the breakdown spot 401 occurs near a center of the gate electrode 302. A flow of the current in dispersion along the gate electrode 302 can be suppressed. Therefore, electromigration of the silicide layer 303a can be performed sufficiently, and variation of the reading-current characteristic distribution after writing can be suppressed.

FIG. 5 is a circuit diagram of a schematic configuration of a memory cell using an antifuse element applied to a nonvolatile semiconductor memory device according to a second embodiment of the present invention.

In FIG. 5, an antifuse element 52 is provided instead of the antifuse element 12 in FIG. 1, in a memory cell 51. While two external terminals are provided in the antifuse element 12 in FIG. 1, three external terminals are provided in the antifuse element 52 in FIG. 5. A field-effect transistor is provided in the antifuse element 52, and data is stored based on a change in conductivity due to breakdown of a gate dielectric film of the field-effect transistor. The gate electrode of the field-effect transistor can use a configuration having a silicide layer laminated on a polycrystalline silicon layer.

A first external terminal of the antifuse element 52 is connected to a source and a drain of the field-effect transistor, a second external terminal of the antifuse element 52 is connected to one end of a gate of the field-effect transistor, and a third external terminal of the antifuse element 52 is connected to the other end of the gate of the field-effect transistor.

The first external terminal of the antifuse element 52 is connected to the memory-cell power source VBP. The second external terminal of the antifuse element 52 is connected to the drain of the write transistor 13 via the write control transistor 15. The third external terminal of the antifuse element 52 is connected to the drain of the read transistor 14 via the read barrier transistor 16.

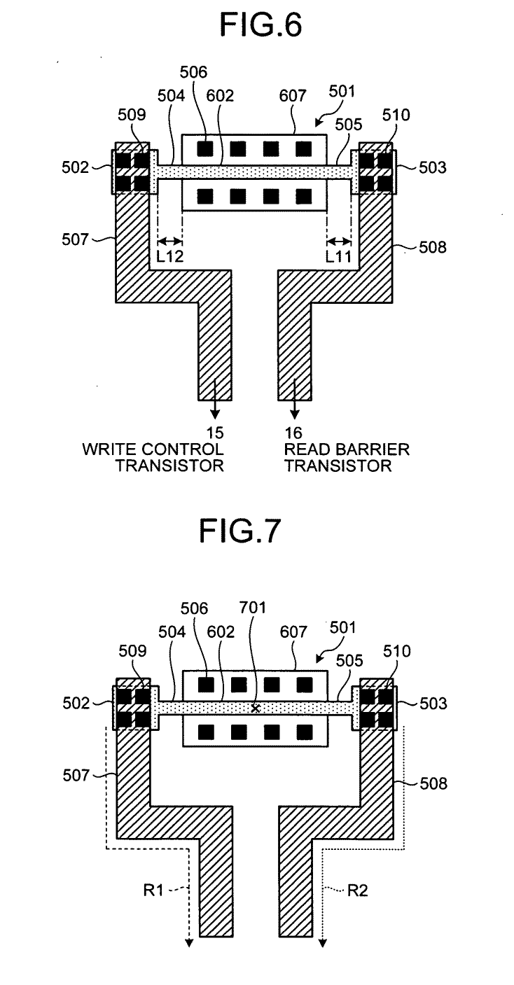

FIG. 6 is a plan view of a schematic configuration of the antifuse element in FIG. 5.

In FIG. 6, a field-effect transistor 501 is provided in the antifuse element 12 in FIG. 1. The field-effect transistor 501 has a gate electrode 602 formed on a semiconductor substrate via a gate dielectric film. An impurity diffusion layer 607 is formed at both sides of the gate electrode 602. A contact 506 that applies a voltage of the memory-cell power source VBP is formed on the impurity diffusion layer 607.

A drawing wiring 504 is drawn out from one end of the gate electrode 602, and is connected to a terminal 502. A drawing wiring 505 is drawn out from the other end of the gate electrode 602, and is connected to a terminal 503. The drawing wirings 504 and 505 and the terminals 502 and 503 can use the same structure as that of the gate electrode 602, and can use a structure having a silicide layer laminated on a polycrystalline silicon layer, for example.

The terminal 502 is connected to a wiring 507 via a contact 509, and the terminal 503 is connected to a wiring 508 via a contact 510. The wirings 507 and 508 can be configured by a metal such as Al and Cu. The wiring 507 is connected to the drain of the write transistor 13 via the write control transistor 15 in FIG. 5. The wiring 508 is connected to the drain of the read transistor 14 via the read barrier transistor 16. A length L12 of the drawing wiring 504 can be set different from, or can be set the same as, a length L11 of the drawing wiring 505.

When data is written into the antifuse element 52 in FIG. 5, a high voltage is applied to the impurity diffusion layer 607 from the memory-cell power source VBP, and a low voltage is applied to one end of the gate electrode 602 from the write bit line BLW. At this time, the difference between potentials applied to the impurity diffusion layer 607 and the gate electrode 602 can be a voltage sufficient enough to break down a gate dielectric film, for example, about 6 volts.

When voltages sufficient enough to break down the gate dielectric film are applied to the impurity diffusion layer 607 and the one end of the gate electrode 602, a part of the gate dielectric film is broken down. As a result, a breakdown spot 701 is formed in the gate dielectric film, as shown in FIG. 7. When the breakdown spot 701 is formed in the gate dielectric film, a current flows to the gate electrode 602 via the breakdown spot 701, and a current path R1 is formed.

On the other hand, when data is read from the antifuse element 52 in FIG. 5, a low voltage of about not breaking down the gate dielectric film is applied from the memory-cell power source VBP to the impurity diffusion layer 607. A current flows to the read bit line BLR via a current path R2 corresponding to a breakdown state of the gate dielectric film of the antifuse element 52. Whether data stored in the antifuse element 52 is “0” or “1” is determined based on a size of a reading current obtained at this time.

The current path R2 at a reading time can be set different from the current path R1 at a writing time, by writing data from one end of the gate electrode 602 and by reading data from the other end of the gate electrode 602. As a result, a stable reading characteristic can be achieved, and variation in the reading-current characteristic distribution after writing can be suppressed, even when electromigration of metal silicide generated at the writing time is unstable.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
a field-effect transistor having a gate electrode formed on a semiconductor substrate via a gate dielectric film;
a first drawing wiring drawn out from one end of the gate electrode;
a second drawing wiring drawn out from the other end of the gate electrode and having a length different from that of the first drawing wiring;
a first terminal that applies a voltage to the gate electrode via the first drawing wiring;
a second terminal that applies a voltage to the gate electrode via the second drawing wiring; and
a wiring that is connected to the first terminal and the second terminal, supplies a voltage used to break down the gate dielectric film, and is used to read a change in a resistance following breakdown of the gate dielectric film.

2. The nonvolatile semiconductor memory device according to claim 1, wherein the first drawing wiring and the second drawing wiring have a same structure as that of the gate electrode.

3. The nonvolatile semiconductor memory device according to claim 2, wherein the gate electrode, the first drawing wiring, the second drawing wiring, the first terminal, and the second terminal have a structure having a silicide layer laminated on a polycrystalline silicon layer.

4. The nonvolatile semiconductor memory device according to claim 3, wherein when voltages sufficient enough to break down the gate dielectric film are applied to the impurity diffusion layer and the gate electrode of the field-effect transistor, a breakdown spot is formed in the gate dielectric film, and a relatively low-resistance conductive path is formed between the silicide layer on the impurity diffusion layer and the silicide layer on the gate electrode.

5. The nonvolatile semiconductor memory device according to claim 1, wherein one of the first drawing wiring and the second drawing wiring is set to have a wiring length equal to or larger than a gate width of the gate electrode.

6. The nonvolatile semiconductor memory device according to claim 1, further comprising:
a write control transistor having a drain connected to the wiring;
a read barrier transistor having a drain connected to the wiring;
a write transistor connected in series to the write control transistor;
a read transistor connected in series to the read barrier transistor;
a write word line connected to a gate of the write transistor;
a read word line connected to a gate of the read transistor;
a write bit line connected to a source of the write transistor; and
a read bit line connected to a source of the read transistor.

7. The nonvolatile semiconductor memory device according to claim 6, further comprising a row decoder that selects the write word line and the read word line based on a row address signal.

8. The nonvolatile semiconductor memory device according to claim 7, wherein
the row decoder comprises:
a row-selection logic circuit that selects a row based on the row address signal;
a write-word-line drive circuit that drives the write word line based on an output of the row-selection logic circuit and a write-operation control signal; and
a read-word-line drive circuit that drives the read word line based on an output of the row-selection logic circuit and a write-operation control signal.

9. The nonvolatile semiconductor memory device according to claim 8, further comprising:
a read sense amplifier that determines whether data stored in a selected cell is “0” or “1” by comparing a potential of the read bit line with a reference potential; and
a write-disturbance protection circuit that sets a potential of the read bit line at a power source potential based on the write control signal.

10. A nonvolatile semiconductor memory device comprising:
a field-effect transistor having a gate electrode formed on a semiconductor substrate via a gate dielectric film;
a first drawing wiring drawn out from one end of the gate electrode;
a second drawing wiring drawn out from the other end of the gate electrode;
a first terminal that applies a voltage to the gate electrode via the first drawing wiring;
a second terminal that applies a voltage to the gate electrode via the second drawing wiring;
a first wiring that is connected to the first terminal and supplies a voltage used to break down the gate dielectric film; and
a second wiring that is connected to the second terminal and is used to read a change in a resistance following breakdown of the gate dielectric film.

11. The nonvolatile semiconductor memory device according to claim 10, wherein the first drawing wiring and the second drawing wiring have a same structure as that of the gate electrode.

12. The nonvolatile semiconductor memory device according to claim 11, wherein the gate electrode, the first drawing wiring, the second drawing wiring, the first terminal, and the second terminal have a structure having a silicide layer laminated on a polycrystalline silicon layer.

13. The nonvolatile semiconductor memory device according to claim 10, further comprising:
a write control transistor having a drain connected to the first wiring;
a read barrier transistor having a drain connected to the second wiring;
a write transistor connected in series to the write control transistor;
a read transistor connected in series to the read barrier transistor;
a write word line connected to a gate of the write transistor;
a read word line connected to a gate of the read transistor;
a write bit line connected to a source of the write transistor; and
a read bit line connected to a source of the read transistor.

14. The nonvolatile semiconductor memory device according to claim 13, further comprising a row decoder that selects the write word line and the read word line based on a row address signal.

15. The nonvolatile semiconductor memory device according to claim 14, wherein
the row decoder comprises:
a row-selection logic circuit that selects a row based on the row address signal;
a write-word-line drive circuit that drives the write word line based on an output of the row-selection logic circuit and a write-operation control signal; and
a read-word-line drive circuit that drives the read word line based on an output of the row-selection logic circuit and a write-operation control signal.

16. The nonvolatile semiconductor memory device according to claim 15, further comprising:
a read sense amplifier that determines whether data stored in a selected cell is “0” or “1” by comparing a potential of the read bit line with a reference potential; and
a write-disturbance protection circuit that sets a potential of the read bit line at a power source potential based on the write control signal.

17. A nonvolatile semiconductor memory device comprising:
a gate electrode arranged via a gate dielectric film to cross an impurity diffusion layer on a semiconductor substrate;
a first wiring that supplies a voltage used to break down the gate dielectric film via one end of the gate electrode; and
a second wiring that reads a change in a resistance following breakdown of the gate dielectric film via the other end of the gate electrode.

18. The nonvolatile semiconductor memory device according to claim 17, further comprising:
a write control transistor having a drain connected to the first wiring;
a read barrier transistor having a drain connected to the second wiring;
a write transistor connected in series to the write control transistor;
a read transistor connected in series to the read barrier transistor;
a write word line connected to a gate of the write transistor;
a read word line connected to a gate of the read transistor;
a write bit line connected to a source of the write transistor; and
a read bit line connected to a source of the read transistor.

19. The nonvolatile semiconductor memory device according to claim 18, further comprising a row decoder that selects the write word line and the read word line based on a row address signal.

20. The nonvolatile semiconductor memory device according to claim 19, wherein
the row decoder comprises:
a row-selection logic circuit that selects a row based on the row address signal;
a write-word-line drive circuit that drives the write word line based on an output of the row-selection logic circuit and a write-operation control signal; and
a read-word-line drive circuit that drives the read word line based on an output of the row-selection logic circuit and a write-operation control signal.
